(19) United States
(12) Patent Application Publication
(10) Pub. No.: US 2021/0242359 A1
(43) Pub. Date: Aug. 5, 2021

(54) SEMI-TRANSPARENT THIN-FILM PHOTOVOLTAIC DEVICE PROVIDED WITH AN OPTIMIZED METAL/NATIVE OXIDE/METAL ELECTRICAL CONTACT

(71) Applicant: Garmin Switzerland GmbH, Schaffhausen (CH)

(72) Inventor: Mohamed Bouchoucha, Les Pennes Mirabeau (FR)

(21) Appl. No.: 17/238,891

(22) Filed: Apr. 23, 2021

Related U.S. Application Data
(63) Continuation of application No. PCT/IB2019/059164, filed on Oct. 25, 2019.

(30) Foreign Application Priority Data
Oct. 26, 2018 (FR) FR1801136

(51) Int. Cl. H01L 31/05

(52) U.S. Cl. CPC H01L 31/0512; H01L 31/0508

(57) ABSTRACT

A thin-film semi-transparent photovoltaic device comprising: a plurality of active photovoltaic zones, having a surface S₅, formed of: a transparent substrate; a front electrode formed of a transparent electroconductive material arranged on the transparent substrate; an absorber made up of one or more photoactive thin layer(s); a rear electrode formed of a stack of at least: a conductive metal layer; and a native metal oxide layer having a nanometric thickness. The device additionally includes a plurality of transparent zones separating at least two active photovoltaic zones; and a metal reconnection layer having a contact surface S to the rear electrode, wherein the ratio Rₐ=S/S₅ between the contact surface S of the metal reconnection layer and the surface S₅ of an active photovoltaic zone is such that 0.2%<Rₐ<2%.

### RELATED APPLICATIONS

The present application is a continuation of, and claims priority benefit to, co-pending international application entitled, “SEMI-TRANSPARENT THIN-FILM PHOTOVOLTAIC DEVICE PROVIDED WITH AN OPTIMIZED METAL/NATIVE OXIDE/METAL ELECTRICAL CONTACT,” International Application No. PCT/IB2019/059164, filed Oct. 25, 2019, which claims priority to French Patent Application No. 1801136, filed Oct. 26, 2018. Each of the above-referenced applications are hereby incorporated by reference into the current application in their entirety.

### BACKGROUND

A photovoltaic device refers to any type of cells or photovoltaic modules. The photovoltaic modules are made up of a plurality of photovoltaic cells which are all interconnected according to a series, parallel, series-parallel or parallel-series architecture. A thin-film photovoltaic device refers to photovoltaic devices made up of a stack of thin layers having a thickness of less than 20 μm (excluding the substrate).

In the literature, a distinction is made among a plurality of types of semi-conductor materials used in the photovoltaic devices, such as crystallized solid materials, organic materials (polymers or small molecules) or indeed the inorganic thin layers (amorphous or polycrystalline). In most cases, a metal layer is used to collect the electrical charges generated by said devices under illumination. Said metal layers generally form an electrode, collector buses, or the interconnections between the different cells that make up the photovoltaic module.

In order to improve the performance of the photovoltaic modules, it is known to a person skilled in the art that increasing for example the thickness of the metal electrodes makes it possible to reduce the losses resulting from the Joule effect. In this case, it is therefore necessary to bring a metal A, that has been in the open air (the metal electrode of the initial cell), into contact with another conductor B in order to thicken said electrode and thus increase the overall conductivity thereof. However, some metals, including aluminum (Al) and copper (Cu), which are commonly used to form, for example, the metal electrode of the thin-film photovoltaic devices, undergo surface oxidation in the open air, or indeed in atmospheres in which the oxygen levels are controlled. Thus, an oxide commonly referred to as a native oxide is formed. Said fine layer of native oxide, having a thickness of a few nanometers, is mostly electrically insulating. This is the case in particular for aluminum and copper oxides. In this case, the stack made up of the metal electrode A, the oxide thereof, and the conductor B, does not have an improved conductivity as hoped for due to the a posteriori thickening of the metal electrode, since the electrical contact resistance between the two metals is very significant on account of the presence of the native oxide between the two metals. The same phenomenon is observed when attempting to place a plurality of photovoltaic cells in series or in parallel, a posteriori, in order to control the voltage and current levels at the output of the photovoltaic modules.

The semi-transparent thin-film photovoltaic devices (based on amorphous silicon for example) are made up of: solid and opaque surfaces containing the stack of active photovoltaic layers; and transparent surfaces formed by the transparent substrate and optionally by transparent conductive or insulating materials.

The semi-transparency may for example be achieved using solid photovoltaic modules, i.e. not having transparent zones as described in WO2014/188092 A1. The photovoltaic zones (or the transparent zones) may be of any shape whatsoever. Thus, the critical dimension of said shape is defined as being the smallest of the measurements characterizing it. It is, for example, a side for a square, a width for a rectangle, and the height for a triangle. For example, in the case of a photovoltaic strip, the critical dimension CD corresponds to the width of said strip. When a homogeneous transparent appearance is desired (i.e. when it is not desired to distinguish, with the naked eye, the opaque zones from the transparent zones), the critical dimension of the photovoltaic strips is preferably less than 200 microns.

Following the etching of the various layers making up the photovoltaic stack (the first electrode, the active photovoltaic layer, and the second electrode), reconnections of the metal/metal type are necessary in order to connect the electrically active zones to the collector buses and to interconnect the unitary cells (in series and/or in parallel) in order to obtain a photovoltaic module. The problem of metal/metal reconnection is reinforced in the case of semi-transparent photovoltaic devices, since the reconnections are made on surfaces of which the wider sides do not exceed a few tens of micrometers, thus producing reconnection surfaces of a few micrometers square. However, if the metal oxide is of aluminum, the native oxide thereof (alumina) may have a thickness of from 3 nm to 6 nm. The combination of said material with a contact surface of barely a few hundredths of micrometers square results in precarious electrical contact, resulting in a deterioration in the electrical efficiency of the device.

A first solution consists in suppressing the alumina layer which is formed at the surface thereof before the deposition of the second metal allowing for the reconnection. It is possible to use, for example, plasma etching, and to deposit the second metal immediately thereafter, without having broken the vacuum conditions between the etching step and that of metal deposition. This step requires deposition equipment having a plasma module in the deposition chamber or in an adjoining chamber. This configuration may not be available in production equipment, in which case the investment for upgrading it may be significant.

A second solution for overcoming this problem would be that of modifying the nature of the metal electrode. This solution is not of interest from an industrial perspective, since aluminum is a preferred material in the field of photovoltaic modules based on amorphous silicon due to:
its low cost;
its low resistivity;
its compatibility with the material of the active photovoltaic layer, in particular in the case of amorphous silicon;
its ability to link the etching steps in order to generate the semi-transparency;
its availability and its mastery by manufacturers of deposition and etching methods.

Semi-transparent thin-film photovoltaic devices which seek to improve the performance of layers of devices with respect to mechanical stresses are also known from US 2010/163106 A1 and US 2011/287568 A1, but said devices do not address the dimension of the reconnection and the electrical consequences thereof.

### SUMMARY

Embodiments of the present invention relate to a semi-transparent thin-film photovoltaic device which optimizes the metal/native oxide/metal reconnection by the dimensioning of the contact surface of the second deposited metal.

Various embodiments provide a thin-film semi-transparent photovoltaic device comprising: a plurality of active photovoltaic zones, having a surface S₅, formed of: a transparent substrate; a front electrode formed of a transparent electroconductive material arranged on the transparent substrate; an absorber made up of one or more photoactive thin layer(s); a rear electrode formed of a stack of at least: a conductive metal layer; and a native metal oxide layer having a nanometric thickness. The device additionally includes a plurality of transparent zones separating at least two active photovoltaic zones; and a metal reconnection layer having a contact surface S to the rear electrode, wherein the ratio Rₐ=S/S₅ between the contact surface S of the metal reconnection layer and the surface S₅ of an active photovoltaic zone is such that 0.2%<Rₐ<2%.

The ratio Rₐ is defined as the ratio between the contact surface S of the metal reconnection layer and the surface S₅ of an active photovoltaic zone, i.e. Rₐ=S/S₅. During the manufacture of reconnections within semiconductor devices, a person skilled in the art would use the ratio Rₐ of the order of 0.02%. However, using said ratio in the semi-transparent thin-film photovoltaic device described above, the electrical optimization of the reconnection is not achieved. In order to achieve this electrical optimization, it is desirable to use a ratio Rₐ of between 0.2% and 2%, i.e. 0.2%<Rₐ<2%.

In some embodiments, to ensure the best compromise between the active photovoltaic surface and electrical optimization, the ratio Rₐ is advantageously between 1.2% and 1.6%, i.e. 1.6%<Rₐ<1.8%. In some examples, The conductive metal layer is made of aluminum, and the native oxide thereof is thus alumina. The metal reconnection layer may also be made of aluminum.

The contact surface of the metal reconnection layer may be of any shape whatsoever. It can also be made up of a plurality of patterns of any shape whatsoever, which are all electrically interconnected.

When the semi-transparent photovoltaic modules have a strip architecture, the active photovoltaic zones are strips of length L₅ and critical dimension CD₅. Advantageously, the contact surface S between the metal reconnection layer and the rear electrode is rectangular in shape, the width, i.e. the critical dimension CD, of which is less than the critical dimension CD₅ of the photovoltaic zones.

### BRIEF DESCRIPTION OF THE DRAWING FIGURES

FIG. 1A is a cross section of a thin-film photovoltaic stack.

FIG. 1B is a plan view of the photovoltaic stack of FIG. 1A, within which a plurality of thin layers have been etched in regions in order to form transparent zones and active photovoltaic zones.

FIG. 1C is a plan view of the photovoltaic device of FIG. 1B, to which the metal reconnection zones according to the invention have been added.

FIG. 1D is a cross section according to the direction X of FIG. 1C.

FIG. 1E is a cross section taken from FIG. 1D, to which the insulation layer has been added.

FIG. 1F is a cross section taken from FIG. 1E, to which the metal reconnection layers have been added.

FIG. 2A is a diagram of a part of a semi-transparent photovoltaic cell according one embodiment of the invention.

FIG. 2B shows the development of the total electrical resistance R of photovoltaic devices having the same intrinsic characteristics, as a function of the length L of the rectangular contact surface.

FIG. 3A and FIG. 3B are diagrams of photovoltaic cells which are similar to FIG. 2A and correspond to other embodiments of the invention.

FIG. 3C shows another example photovoltaic cell.

### DETAILED DESCRIPTION

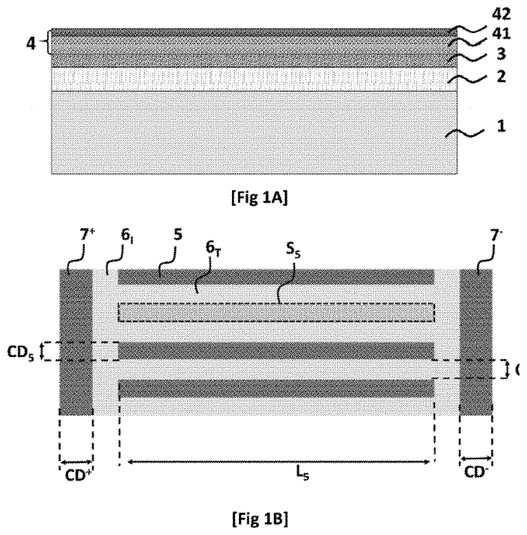

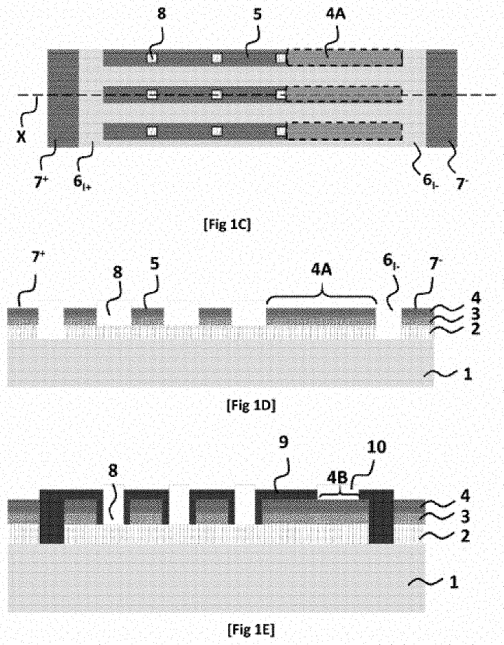

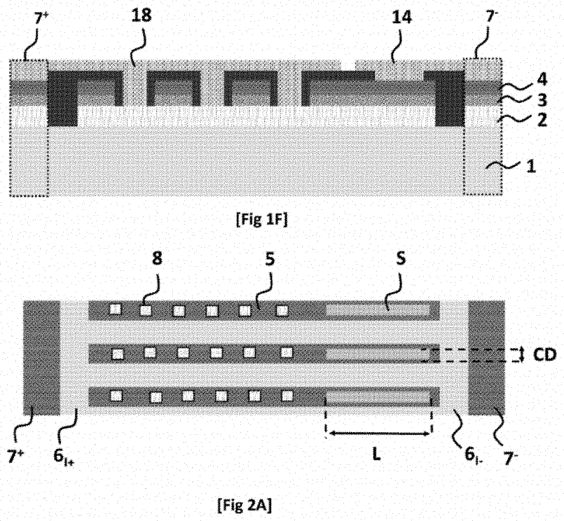

FIG. 1A is a cross section of an example photovoltaic stack. In this example, the stack is made up of:
a glass substrate (1);
a front electrode (2) formed of a transparent conductive oxide, for example aluminum-doped zinc oxide (ZnO:Al);
an absorber (3) made up of a plurality of layers based on amorphous silicon (a_Si) forming a p-i-n junction; and
a rear electrode (4) formed of:
   a layer of aluminum (41);
   a native oxide layer (42) of alumina.

It is possible to transform said stack, by means of photolithographic etching methods and deposition methods known to a person skilled in the art, in order to obtain a semi-transparent photovoltaic module. The first step of this method consists in forming transparent zones (6_{T}), and in electrically insulating the collector buses (7+, 7−) by means of insulation zones (6_{I}). The transparent and insulation zones (6_{T} and 6_{I}) are formed by successive etching of the thin layers forming the rear electrode, the absorber and the front electrode.

FIG. 1B is a plan view of semi-transparent photovoltaic cells, the transparent zones (6_{T}) of which are in the shape of mutually parallel horizontal strips which separate, in pairs, the opaque active photovoltaic zones (5) having a critical dimension CD₅ (corresponding in this case to the width thereof) and a length L₅. The surface S₅ of the photovoltaic strip is thus equal to the product of the critical dimension CD₅ times the length L₅. The vertical opaque strips are the collector buses (7⁺ and 7⁻) which are electrically insulated from the active photovoltaic zones (5). The collector buses (7⁺ and 7⁻, respectively) have a critical dimension denoted CD⁺ and CD⁻, respectively. The transparent zones (6_{T}) electrically insulate the active photovoltaic strips (5), each of said strips forming unitary photovoltaic cells. The transparent zones (6_{T}) have a critical dimension denoted CD_{T}.

In order to electrically connect (in series and/or parallel) said insulated active photovoltaic zones to the collector buses (7⁺ and 7⁻) so as to obtain a photovoltaic module, it is necessary to implement electrical contact between the front electrode (2) and one of the collector buses (7⁺), and electrical contact between the rear electrode (4) and the other collector bus (7⁻).

The implementation of a reconnection of the VIA (8) type and of the rear electrode (4) type comprises a plurality of successive steps which may be implemented simultaneously.

Step 1: Reconnection zones of the VIA (8) type are etched within the active photovoltaic zones (5). An active photovoltaic zone (4A) close to the collector bus (7⁻) is left without a VIA. It is precisely within this zone that the reconnection between the rear electrode (4) and the metal layer (14) takes place, the dimensioning of which is addressed by the invention. FIG. 1D is a cross section of FIG. 1C according to the direction X, where the reconnection zones of the VIA (8) type appear and the active photovoltaic zone (4A) in the vicinity of the collector bus (7⁻) is left without a VIA.

Step 2: An electrical insulation layer (9) is introduced in order to electrically insulate the front electrode (2) from the rear electrode (4). FIG. 1E is a cross section taken from FIG. 1D, to which the insulation layer (9) has been added. This electrical insulation layer is for example a transparent, permanent and photosensitive resin. Rear reconnection zones (4B) are left vacant within the active photovoltaic zones (4A) available for the reconnection of the rear electrode, in order to implement the reconnection on the metal (4).

Step 3: A metal reconnection layer is thus deposited and etched. It is thus split into two distinct zones (18 and 14), as shown in FIG. 1F. It may be etched for example, by way of a new photolithography step, in order to connect the front electrode (2) to the collector bus (7⁺) and the rear electrode (4) to the collector bus (7⁻), in order to make the semi-transparent photovoltaic module functional.

Example embodiments of the invention aims to improve the reconnection between the rear electrode (4) and the collector bus (7⁻) by optimizing the contact surface S between the rear electrode (4) and the metal reconnection layer (14).

In order to determine the optimal characteristics of said contact surface, a plurality of semi-transparent thin-film photovoltaic devices have been produced, an example of which is described in FIG. 2A. Said devices have the same physical and architectural characteristics. The manufacturing process is entirely identical for all the versions of said devices produced. Said devices differ merely by the contact surface S between the rear electrode (4) and the metal reconnection layer (14). In said devices, the surface S is rectangular in shape, has a critical dimension CD of 8 μm, and a length L. Said length L varies from 80 μm to 960 μm, depending on the device in question.

The total surface of said devices is 2.5 cm by 2.5 cm, i.e. 6.26 cm², having an area ratio of transparent zones of 50%. Said devices comprise:
a glass transparent substrate (1);
a front electrode (2) formed of aluminum-doped zinc oxide (ZnO:Al);
an absorber (3) consisting substantially of amorphous silicon (a_Si);
a metal rear electrode (4) formed of:
   a layer of aluminum (40) of 500 nm and having a mean square surface roughness of 15 nm;
   a native oxide layer (41) of alumina of 4 nm;
two collector buses (7⁺ and 7⁻) having a critical dimension CD⁺ and CD⁻ of 1 mm;
active photovoltaic zones (5), the critical dimension CD₅ of which is 15 μm and the length L₅ of which is 23 mm, thus having a surface S₅ of 345,000 μm²;
transparent zones (6_{T}), the critical dimension CD_{T} of which is 15 μm,
a metal reconnection layer (14) of metal/native oxide/metal made of aluminum of 500 nm thickness, deposited by spraying, in equipment which does not make it possible to carry out plasma etching of the native alumina.

The theoretical total electrical resistance was calculated on the basis of modeling of resistances of different materials making up said devices, known to a person skilled in the art. Thus, the interface resistances, including the metal/native oxide/metal contact resistance, are not taken into account in this calculation. The theoretical total resistance R_{TH} is estimated at 120Ω.

Current/voltage (I-V) measurements have made it possible to determine the real values of the total electrical resistances of each device. The curve 9_{TH} of FIG. 2B shows the development of the theoretical total electrical resistance R_{TH} as a function of the length L. In reality, the curve 9_{TH} is a horizontal straight line, which means that the contact resistance does not depend on the length L and is negligible with respect to the resistance of the different materials which make up the device, in accordance with the prior art. The curve 9 of FIG. 2B shows the development of the total electrical resistance R of the devices produced, as a function of the length L. Surprisingly, said curve exhibits an exponential decay as a function of the length L. For a length of 80 μm, the total electrical resistance is 2,500Ω, i.e. 20 times greater than the theoretical total electrical resistance estimated at 120Ω for said devices. The greater the length L, the smaller the total electrical resistance R. The curve profile tends towards a horizontal asymptote around 150Ω. The difference of 30Ω compared with the theoretical value can be explained by errors in the estimation of the resistivities and thicknesses of materials and/or the failure to take into account the interface resistances.

It is considered that the contact is optimized when the total electrical resistance R reaches 125% of the value obtained by virtue of the asymptote of the curve. In this case, this corresponds to a value L=800 μm, and thus to a surface S of 6,400 μm². The ratio of the surface is Rₐ=S/S₅=6,400/345,000=0.018=1.8%. Now, a person skilled in the art would have used a metal reconnection layer consisting of metal/native oxide/metal of the order of magnitude of the critical dimension of the photovoltaic strip but slightly smaller than said strip, i.e. for example a surface of the order of 14*14 μm²=196 μm², i.e. a ratio of barely Rₐ=196/345,000=0.057%. In this example, between the optimization according to the invention and the predictable selection of a person skilled in the art, there is a ratio of 32 between the two surfaces of the metal reconnection layer consisting of metal/native oxide/metal.

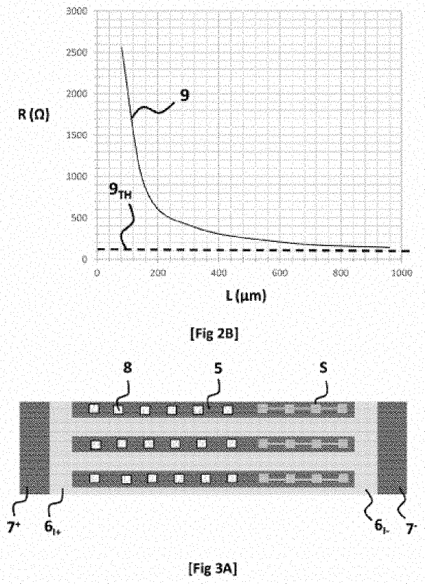

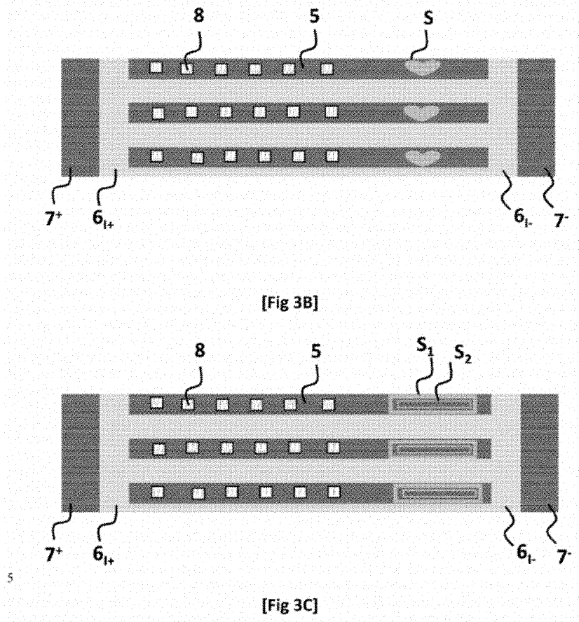

Although the example of FIG. 2A, set out above, relates to a rectangular shape, the contact surface may be of any desired shape. For reasons of photolithographic methods, patterns different from those shown in FIG. 2A may be selected for overcoming the problems of definition of patterns for the lithography or the etching for example. An example is shown in FIG. 3A. The contact surface is thus formed by small rectangles of the same dimension as the VIAs, which are electrically interconnected. However, any continuous shape may be suitable for meeting the criteria of the invention, even a heart-shaped pattern as proposed in FIG. 3B.

According to the invention, the optimization of the contact surface is achieved only if all the different parts of said surface are in electrical contact. For example, in the embodiment of [FIG. 3C], the surface S is made up of the surfaces S₁+S₂. However, S₁ and S₂ are not electrically interconnected, and therefore this arrangement does not allow for the optimization according to the invention.

TABLE 1

| | |
|---|---|
| 1 | Substrate |
| 2 | Front electrode |
| 3 | Absorber |
| 4A | Active photovoltaic zone available for the reconnection of the |
| | rear electrode |
| 4B | Reconnection zone of the rear electrode |
| 40 | Metal layer of the rear electrode |
| 41 | Native oxide of the metal layer of the rear electrode |
| 5 | Active photovoltaic zones |
| L₅ | Length of a photovoltaic strip |
| CD₅ | Critical dimension of a photovoltaic strip |
| CD_{T} | Critical dimension of a transparent strip |
| CD | Critical dimension of the metal reconnection layer (14) |
| CD⁺, CD⁻ | Critical dimension of the collector buses |
| S₅ | Surface of a photovoltaic strip |
| 6_{T} | Transparent zones |
| 6_{I} | Insulation zone |
| 7⁺, 7⁻ | Collector bus |
| 8 | Reconnection of the metal grid, VIA |
| 9 | Insulation layer |
| 10 | Ambient air surrounding the photovoltaic device |
| 14 | Metal reconnection layer consisting of metal/native oxide/metal |
| 18 | Metal reconnection layer of the VIA type |

1. A semi-transparent thin-film photovoltaic device comprising:
a plurality of active photovoltaic zones, having a surface S₅, formed of:
a transparent substrate;
a front electrode formed of a transparent electroconductive material arranged on the transparent substrate;
an absorber made up of one or more photoactive thin layers; and
a rear electrode formed of a stack of at least:
a conductive metal layer; and
a native metal oxide layer having a nanometric thickness;
a plurality of transparent zones separating at least of the two active photovoltaic zones; and
a metal reconnection layer having a contact surface S to the rear electrode;
wherein the ratio Rₐ=S/S₅ between the contact surface S of the metal reconnection layer and the surface S₅ of an active photovoltaic zone is such that 0.2%<Rₐ<2%.

2. The device of claim 1, wherein the ratio Rₐ is such that 1.6%<Rₐ<2%.

3. The device of claim 1, wherein the conductive metal layer is made of aluminum and the native oxide layer is made of alumina.

4. The device of claim 1, wherein the metal reconnection layer is made of aluminum.

5. The device of claim 1, wherein the contact surface of the metal reconnection layer includes a plurality of electrically interconnected patterns.

6. The device of claim 1, wherein the contact surface S between the metal reconnection layer and the rear electrode is rectangular in shape.

7. A semi-transparent thin-film photovoltaic device comprising:
a plurality of active photovoltaic zones, having a surface S₅, formed of:
a transparent substrate;
a front electrode formed of a transparent electroconductive material arranged on the transparent substrate;
an absorber made up of one or more photoactive thin layers; and
a rear electrode formed of a stack of at least:
a conductive metal layer; and
a native metal oxide layer having a nanometric thickness;
a plurality of transparent zones separating at least of the two active photovoltaic zones; and
a metal reconnection layer having a contact surface S to the rear electrode;
wherein the ratio Rₐ=S/S₅ between the contact surface S of the metal reconnection layer and the surface S₅ of an active photovoltaic zone is such that 1.6%<Rₐ<2%.

8. The device of claim 7, wherein the conductive metal layer is made of aluminum and the native oxide layer is made of alumina.

9. The device of claim 7, wherein the metal reconnection layer is made of aluminum.

10. The device of claim 7, wherein the contact surface of the metal reconnection layer includes a plurality of electrically interconnected patterns.

11. The device of claim 7, wherein the contact surface S between the metal reconnection layer and the rear electrode is rectangular in shape.
